(19) United States
(12) Patent Application Publication
(10) Pub. No.: US 2025/0040171 A1
(43) Pub. Date: Jan. 30, 2025

(54) SEMICONDUCTOR DEVICE HAVING A DOPED REGION UNDERLYING A GATE LAYER AND IN A BARRIER LAYER

(71) Applicant: TEXAS INSTRUMENTS INCORPORATED, Dallas, TX (US)

(72) Inventor: Dong Seup Lee, McKinney, TX (US)

(21) Appl. No.: 18/359,991

(22) Filed: Jul. 27, 2023

(51) Int. Cl. H01L 29/778; H01L 23/31; H01L 29/20; H01L 29/66

(52) U.S. Cl. CPC H01L 29/7786; H01L 23/3171; H01L 29/2003; H01L 29/66462

(57) ABSTRACT

The present disclosure generally relates to a semiconductor device having a doped region underlying a gate layer and in a barrier layer. In an example, a semiconductor device includes a channel layer, a barrier layer, and a gate layer. The channel layer is over a semiconductor substrate, and the barrier layer is over the channel layer. The gate layer is over the barrier layer, and the gate layer is doped with a dopant. A first region in the barrier layer overlies a channel region in the channel layer and underlies the gate layer. The first region has a first concentration of the dopant. A second region in the barrier layer is laterally disposed from the first region. The second region has a second concentration of the dopant that is less than the first concentration.

### BACKGROUND

A type of semiconductor device is a high electron mobility transistor (HEMT). A HEMT typically employs different semiconductor materials to form a heterojunction, where a channel may be formed near the heterojunction and between a source region and a drain region. A HEMT may support a high speed operation, which makes HEMTs attractive for high frequency applications, among others.

### SUMMARY

An example described herein is a semiconductor device. The semiconductor device includes a channel layer, a barrier layer, and a gate layer. The channel layer is over a semiconductor substrate, and the barrier layer is over the channel layer. The gate layer is over the barrier layer, and the gate layer is doped with a dopant. A first region in the barrier layer overlies a channel region in the channel layer and underlies the gate layer. The first region has a first concentration of the dopant. A second region in the barrier layer is laterally disposed from the first region. The second region has a second concentration of the dopant that is less than the first concentration.

Another example is a method. A doped gate layer is formed over a barrier layer. The doped gate layer is doped with a dopant while forming the doped gate layer. The barrier layer is over a channel layer, and the channel layer is over a semiconductor substrate. The doped gate layer is patterned. After patterning the doped gate layer, a thermal process is performed on the doped gate layer and the barrier layer. The thermal process causes the dopant to diffuse from the doped gate layer into the barrier layer.

A further example is a semiconductor device. The semiconductor device includes a GaN channel layer, an AlGaN barrier layer, a doped GaN gate layer, and a drain contact. The GaN channel layer is over a semiconductor substrate. The AlGaN barrier layer is over the GaN channel layer. The doped GaN gate layer is on the AlGaN barrier layer. The drain contact contacts the AlGaN barrier layer. The doped GaN gate layer includes a p-type dopant. A first portion of the AlGaN barrier layer under the doped GaN gate layer includes a first concentration of the p-type dopant. A second portion of the AlGaN barrier layer between the doped GaN gate layer and the drain contact includes a second concentration of the p-type dopant less than the first concentration.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 illustrates a cross section view of a semiconductor device according to some examples.

FIGS. 2, 3, 4, 5, and 6 are cross-sectional views of the semiconductor device of FIG. 1 at various stages of a first method of manufacturing according to some examples.

FIGS. 7 and 8 are cross-sectional views of the semiconductor device of FIG. 1 at various stages of a second method of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to a semiconductor device having a doped region underlying a gate layer and in a barrier layer. In some examples, the semiconductor device is or includes a high electron mobility transistor (HEMT), and more particularly, an enhancement mode HEMT. The semiconductor device includes a channel layer over a semiconductor substrate, a barrier layer over the channel layer, and a gate layer over the channel layer. A first region is in the barrier layer, underlies the gate layer, and overlies a channel region in the channel layer. A second region is in the barrier layer and is laterally disposed from the first region. The first region has a dopant, a concentration of which is greater than a concentration of the dopant in the second region. According to some examples, a higher threshold voltage and increased drain current stability may be achieved by a semiconductor device implementing, among other things, regions in the barrier layer with such concentrations of a dopant. Other benefits and advantages may also be achieved.

Various examples are described subsequently. Although the specific examples may illustrate various aspects of the above generally described features, examples may incorporate any combination of the above generally described features (which are described in more detail in examples below).

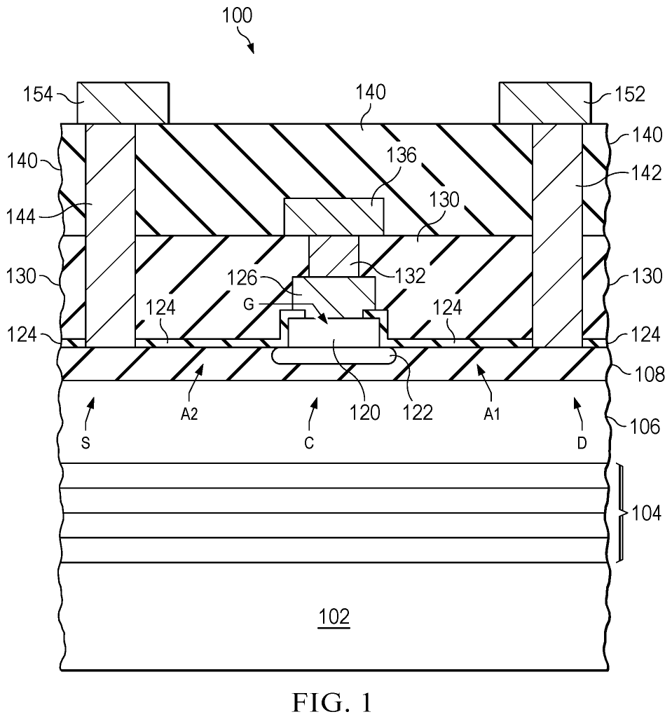

FIG. 1 illustrates a cross section view of a semiconductor device 100 according to some examples. The semiconductor device 100 of FIG. 1 may be or include a HEMT. More particularly, the semiconductor device 100 may be or include an enhancement mode HEMT. Other examples may be or include other types of devices.

FIG. 1 shows a semiconductor substrate 102 and one or more transition layers 104 over and on the semiconductor substrate 102. A channel layer 106 is over and on the uppermost transition layer 104. A barrier layer 108 is over and on the channel layer 106.

The semiconductor substrate 102 may be a bulk semiconductor substrate, a semiconductor-on-insulator (SOI) substrate, or any other appropriate substrate. For example, the semiconductor substrate 102 may be or include bulk silicon wafer. The transition layer(s) 104 may include any number of layers of any materials that are configured to accommodate lattice mismatch between the semiconductor substrate 102 and the channel layer 106 (e.g., to reduce or minimize lattice defect generation and/or propagation in the channel layer 106). For example, the transition layer(s) 104 may have a gradient concentration of one or more elements (e.g., aluminum) in a direction normal to the top surface of the semiconductor substrate 102.

The channel layer 106 is configured, possibly in conjunction with the barrier layer 108, to conduct and confine charge carriers (such as electrons) within two dimensions. In some examples, the channel layer 106 is configured to include a two-dimensional electron gas (2DEG). The 2DEG may be formed by energy band bending (or by conduction-band offset, spontaneous polarization, piezoelectric polarization, etc.) resulting from the barrier layer 108 being over and on the channel layer 106. In some examples, the channel layer 106 includes a gallium nitride (GaN) layer and, in such examples, may be referred to as a GaN channel layer. In some examples, the material of the channel layer 106 is or includes an unintentionally doped material, such as a material doped by diffusion of dopants from another layer or dopants (e.g., carbon) incorporated while forming the channel layer 106. The barrier layer 108, in some examples, may be or include an aluminum gallium nitride (AlGaN) layer and, in such examples, may be referred to as an AlGaN barrier layer. More generally, in some examples, the barrier layer 108 may be or include indium aluminum gallium nitride (InₓAl_{y}Ga_{1-x-y}N) (where 0≤x<1, 0≤y<1, and 0≤x+y≤1). Other materials may be implemented for the channel layer 106 and/or the barrier layer 108.

A gate layer 120 is over and on an upper surface of the barrier layer 108. Further, the gate layer 120 is doped with a dopant. In some examples, the gate layer 120 is doped with a p-type dopant. In some examples, the gate layer 120 may be or include a gallium nitride (GaN) layer, or more generally, indium aluminum gallium nitride (InₓAl_{y}Ga_{1-x-y}N) (where 0≤x<1, 0≤y<1, and 0≤x+y≤1), and the dopant with which the gate layer 120 is doped is a p-type dopant, which may be or include magnesium (Mg), carbon (C), the like, or a combination thereof. In examples in which the gate layer 120 is gallium nitride (GaN) doped with a p-type dopant, the gate layer 120 may be referred to as a p-doped GaN (pGaN) layer. Further, in examples in which the gate layer 120 is gallium nitride (GaN) doped with magnesium, the gate layer 120 may be referred to as a magnesium doped gallium nitride (GaN: Mg) layer. In some examples, a concentration of the dopant in the gate layer 120 (e.g., which may be chemically present by doping, which may include dopants that are electrically activated) is equal to or greater than 1×10¹⁷ cm⁻³, such as equal to or greater than 1×10¹⁹ cm⁻³, and more particularly, equal to or greater than 1×10²⁰ cm⁻³. Other materials, dopants, and/or concentrations may be implemented in other examples.

A doped region 122 is in the barrier layer 108 underlying the gate layer 120. The doped region 122 may extend in the barrier layer 108 from an interface between the gate layer 120 and the barrier layer 108 to a depth in the barrier layer 108 as depicted in FIG. 1. In some examples, the doped region 122 extends from the interface between the gate layer 120 and the barrier layer 108 to the interface between the barrier layer 108 and the channel layer 106. The doped region 122 may further extend laterally a distance from a nearest sidewall surface of the gate layer 120 away from the gate layer 120 in the barrier layer 108. The doped region 122 is doped with a dopant. In some examples, the dopant with which the doped region 122 is doped is a same species of dopant with which the gate layer 120 is doped. For example, the dopant with which the gate layer 120 and the doped region 122 are doped may be a p-type dopant, and more particularly, may be magnesium (Mg), carbon (C), the like, or a combination thereof. In other examples, the doped region 122 and the gate layer 120 may be doped with different dopants. In some examples, a concentration of the dopant in the doped region 122 (e.g., chemically present by doping) is equal to or greater than 1×10¹⁶ cm⁻³, such as equal to or greater than 1×10¹⁸ cm⁻³, and more particularly, equal to or greater than 1×10¹⁹ cm⁻³.

The gate layer 120 may have a gradient concentration of the dopant (e.g., a gradient dopant concentration profile), such as increasing from proximate the interface between the gate layer 120 and the barrier layer 108 to distal from the barrier layer 108. In some examples, an entire thickness of the gate layer 120 may have a gradient concentration of the dopant. In some examples, a first portion of the gate layer 120 (e.g., distal from the barrier layer 108) may have a substantially uniform concentration of the dopant, and a second portion of the gate layer 120 (e.g., proximate to the barrier layer 108) may have a gradient concentration of the dopant. The doped region 122 may also have a gradient concentration of a dopant (e.g., the same dopant as the gate layer 120 or a different dopant than the gate layer 120), such as a decreasing concentration from the interface between the gate layer 120 and the barrier layer 108 to a depth in the barrier layer 108—e.g., to the interface between the barrier layer 108 and the channel layer 106 in some cases. Similarly, the gradient concentration of the doped region 122 may have a decreasing concentration from the interface between the gate layer 120 and the barrier layer 108 to a lateral distance in the barrier layer 108. The concentration profile of the dopant in the gate layer 120 and the doped region 122 may result from the formation of the gate layer 120 and/or from a diffusion mechanism to diffuse the dopant from one or more layers that result in the gate layer 120 into the barrier layer 108 to form the doped region 122. Additional details of such formation and diffusion are described subsequently. The dopant concentration profile may vary depending on different formation and/or diffusion techniques.

The semiconductor device 100 includes a drain region D, a first access region A1, a channel region C, a second access region A2, a source region S, and a gate structure G. The gate structure includes the gate layer 120. The channel region C is in the channel layer 106 underlying the gate structure G. The channel region C is laterally between the drain region D and the source region S, which are also in the channel layer 106. The first access region A1 is in the barrier layer 108 and is laterally between the channel region C and the drain region D, and the second access region A2 is in the barrier layer 108 and is laterally between the channel region C and the source region S. The access regions A1, A2 may be in the barrier layer 108 and the channel layer 106. The doped region 122 is laterally between the first access region A1 and the second access region A2 in the barrier layer 108 and is vertically between the channel region C and the gate layer 120.

The concentration of the dopant in the doped region 122 (e.g., chemically present by doping) is greater than a concentration of the dopant in the first access region A1 in the barrier layer 108 and/or the second access region A2 in the barrier layer 108 (e.g., chemically present by doping). Further, in some examples, the concentration of the dopant in the doped region 122 is an order of magnitude or more (e.g., two or three orders of magnitude or more) greater than a concentration of the dopant in the first access region A1 in the barrier layer 108 and/or the second access region A2 in the barrier layer 108. In some examples, a concentration of the dopant in the first access region A1 and/or second access region A2 in the barrier layer 108 (e.g., chemically present by doping), where the dopant is the dopant with which the doped region 122 is doped, may be equal to or less than 1×10¹⁹ cm⁻³, such as equal to or less than 1×10¹⁷ cm⁻³, and more particularly, equal to or less than 1×10¹⁶ cm⁻³.

A passivation layer 124 is over and on the barrier layer 108 and gate layer 120. The passivation layer 124 may be conformally over and on the barrier layer 108 and the gate layer 120 (e.g., along sidewall surfaces of the gate layer 120 and over and on a top surface of the gate layer 120). In some examples, the passivation layer 124 may be or include silicon nitride, silicon oxide, the like, or a combination thereof. The passivation layer 124 may include one or multiple layers of a same material or different materials. The passivation layer 124 may also be referred to as a dielectric layer.

A gate contact 126 is through an opening through the passivation layer 124 to the gate layer 120. The gate contact 126 is over and contacts the gate layer 120. A portion of the gate contact 126 may be overlying the passivation layer 124 proximate to the opening through which the gate contact 126 contacts the gate layer 120. The gate contact 126 may be or include a metal, such as titanium (Ti), titanium tungsten (TiW), titanium nitride (TiN), nickel (Ni), platinum (Pt), the like, or a combination thereof (such as including a stack including layers of different metal layers). The gate contact 126 may be a metal that forms a Schottky junction or ohmic junction at the interface of the gate contact 126 and the gate layer 120.

A first dielectric layer 130 is over and on the passivation layer 124 and the gate contact 126. The first dielectric layer 130 may be a single dielectric layer or may include multiple dielectric layers of a same dielectric material or different dielectric materials. For example, the first dielectric layer 130 may include a silicon oxide-based material, such as a phosphosilicate glass (PSG) or the like.

A metal via 132 extends through the first dielectric layer 130 and contacts the gate contact 126. A metal line 136 in a first metal layer is over and on the metal via 132 and an upper surface of the first dielectric layer 130. The metal via 132 may include one or more metal-barrier and/or adhesion layers (e.g., titanium nitride (TiN), tantalum nitride (TaN), the like, or a combination thereof) conformally in a respective opening through the first dielectric layer 130, and a fill metal (e.g., tungsten (W), copper (Cu), aluminum (Al), the like, or a combination thereof) over and/or on the metal-barrier and/or adhesion layer(s). The metal line 136 may include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

A second dielectric layer 140 is over and on the first dielectric layer 130 and the metal line 136. The second dielectric layer 140 may include multiple dielectric layers of a same dielectric material or different dielectric materials. For example, the second dielectric layer 140 may include a silicon oxide-based material, such as a PSG, and may further include one or more etch stop layers, such as silicon nitride (SiN) or the like.

A drain contact 142 extends through the second dielectric layer 140, first dielectric layer 130, and passivation layer 124 and contacts the barrier layer 108 on the drain region D, and a source contact 144 extends through the second dielectric layer 140, first dielectric layer 130, and passivation layer 124 and contacts the barrier layer 108 on the source region S. Metal lines 152, 154 in a second metal layer are over and on the contacts 142, 144, respectively, and an upper surface of the second dielectric layer 140. The contacts 142, 144 may each include one or more metal-barrier and/or adhesion layers (e.g., titanium nitride (TiN), tantalum nitride (TaN), the like, or a combination thereof) conformally in a respective opening through the dielectric layers 130, 140 and passivation layer 124, and a fill metal (e.g., tungsten (W), copper (Cu), aluminum (Al), the like, or a combination thereof) over and/or on the metal-barrier and/or adhesion layer(s). The metal lines 152, 154 may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

Although the drain contact 142 and the source contact 144 are depicted to land on the barrier layer 108 in the semiconductor device 100, the present disclosure is not limited thereto. For example, the drain and source contacts 142, 144 may extend into a depth in the barrier layer 108. In some examples, the drain and source contacts 142, 144 may extend through the barrier layer 108 to land on the channel layer 106. In some examples, the drain and source contacts 142, 144 may extend into a depth in the channel layer 106.

Additional dielectric layers and metal layers may be formed over and on the second dielectric layer 140. The first dielectric layer 130, second dielectric layer 140, additional dielectric layers, first metal layer, second metal layer, and additional metal layers may form an interconnect structure. Metal lines in neighboring metal layers may be electrically coupled by metal vias.

The semiconductor device 100 of FIG. 1 may achieve a higher threshold voltage and increased drain current stability. In some cases, a dopant, such as magnesium (Mg), being doped in a gate layer and in access regions in a barrier layer may increase the magnitude of a threshold voltage (vₜ) of an enhancement mode HEMT. The dopant may be used to deplete the 2DEG in the channel layer of the HEMT, which may increase the magnitude of the threshold voltage (vₜ). Increasing the magnitude of the threshold voltage (vₜ) may reduce leakage current. However, having such doping in access regions may result in instability of a drain current (I_{D}) through the HEMT, particularly under high voltage stress. Drain current (I_{D}) could significantly decrease over the duration of a given stress event with doping in access regions. Doping in the access regions can deplete the 2DEG and decrease electron density or can generate traps that trap electrons resulting in increased drain-to-source on resistance (Rds.on) and decreased drain current (I_{D}) during a high voltage stress event. The semiconductor device 100 of FIG. 1 may achieve a higher threshold voltage (vₜ) by maintaining doping in the barrier layer 108 under the gate layer 120 (by the doped region 122). The dopant, such as magnesium (Mg), in the doped region 122 may increase the magnitude of the threshold voltage (vₜ). Further, the relatively reduced dopant in the first access region A1 and second access region A2 in the barrier layer may result in reduced instability of a drain current (I_{D}). Additionally, reducing dopants in the first access region A1 and second access region A2 in the barrier layer may result in decreased dynamic drain-to-source on resistance (R_{ds.on}) and decreased access resistance (R_{access}).

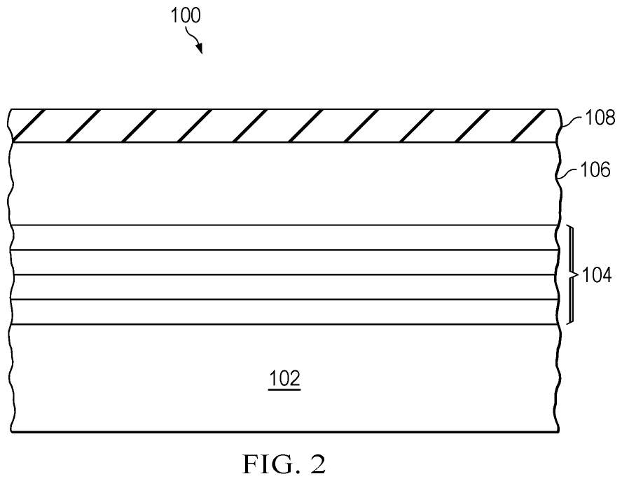

FIGS. 2 through 6 illustrate cross-sectional views of the semiconductor device 100 of FIG. 1 at various stages of a first method of manufacturing according to some examples. Referring to FIG. 2, one or more transition layers 104 are formed over and on a semiconductor substrate 102. The channel layer 106 is formed over and on the transition layer(s) 104, and the barrier layer 108 is formed over and on the channel layer 106. As formed in FIG. 2, the barrier layer 108 may be an un-doped semiconductor material (e.g., is an intrinsic semiconductor material without a p-type or an n-type dopant). Further, the barrier layer 108, in some examples, is in situ doped with neither a p-type nor an n-type dopant during epitaxial growth. In some examples, the transition layer(s) 104, channel layer 106, and barrier layer 108 may be formed by using any appropriate deposition process, which may further be an epitaxial growth process. For example, the transition layer(s) 104, channel layer 106, and barrier layer 108 may each be epitaxially grown using metal-organic chemical vapor deposition (MOCVD), molecular beam epitaxy (MBE), low pressure chemical vapor deposition (LPCVD) or another epitaxy process. The materials of the semiconductor substrate 102, transition layer(s) 104, channel layer 106, and barrier layer 108 may be as described previously.

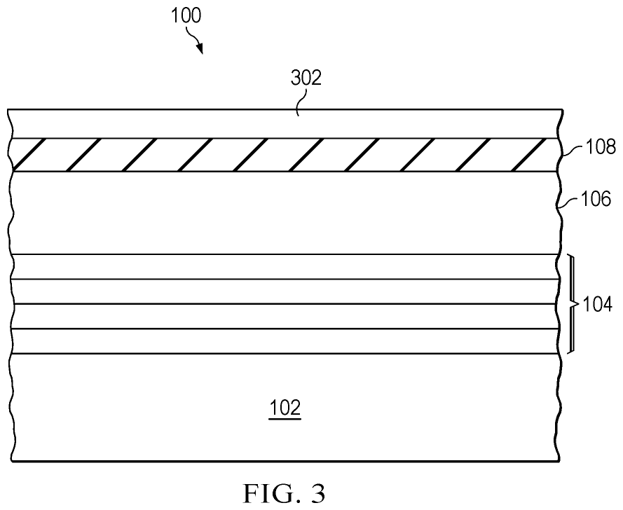

Referring to FIG. 3, a doped gate layer 302 is formed over and on the barrier layer 108. In some examples, the doped gate layer 302 may be epitaxially grown, such as by MOCVD, MBE, LPCVD, plasma enhanced chemical vapor deposition (PECVD), atomic layer epitaxy, or another epitaxy process. The doped gate layer 302 may be doped in situ during deposition (e.g., during epitaxial growth, while forming the doped gate layer 302) or by implantation subsequent to deposition. As formed, the doped gate layer 302 is doped with a dopant, such as a p-type dopant, with a concentration equal to or greater than 1×10¹⁷ cm⁻³, such as equal to or greater than 1×10¹⁹ cm⁻³, and more particularly, equal to or greater than 1×10²⁰ cm⁻³. In some examples, the doped gate layer 302 may be or include a gallium nitride (GaN) layer, or more generally, indium aluminum gallium nitride (InₓAl_{y}Ga_{1-x-y}N), and the dopant with which the doped gate layer 302 is doped is a p-type dopant, which may be or include magnesium (Mg), carbon (C), the like, or a combination thereof. Like described previously, the doped gate layer 302 and/or dopant may be other materials and/or dopants.

In examples in which the doped gate layer 302 is doped in situ during deposition, process parameters for the deposition of the doped gate layer 302 may be tuned to reduce diffusion of the dopant into the barrier layer 108. For example, a process temperature of the deposition, such as MOCVD, may be reduced. A reduction in process temperature may reduce the diffusion of the dopant, such as magnesium (Mg), from the process environment and/or doped gate layer 302 into the barrier layer 108. Similarly, a process pressure of the deposition may be reduced. In some examples, deposition (e.g., epitaxial growth) of the doped gate layer 302 is performed by MOCVD with a processing temperature in a range from 800° C. to 1,050° C. and a processing pressure in a range from 100 millibar (mbar) to 500 mbar. In some examples, deposition of the doped gate layer 302 is performed by MOCVD in which the doped gate layer 302 is in situ doped by flowing a dopant-source gas as a source of the dopant. In some of such examples, a flow rate of the dopant-source gas may be in a range up to 1,000 standard cubic centimeter per minute (sccm). Further, a flow rate of a dopant-source gas of the dopant (e.g., bis(cyclopentadienyl) magnesium (Cp2Mg) gas as a source for magnesium (Mg)) may initially be low and subsequently increased during the deposition of the doped gate layer 302. By having a low flow rate of the dopant-source gas of the dopant initially, a lower amount of dopant may be available proximate to the barrier layer 108 to diffuse into the barrier layer 108, which may reduce diffusion of the dopant into the barrier layer 108 as a result of the deposition. In such situations, as formed, the doped gate layer 302 may have a gradient concentration of the dopant, where the gradient concentration increases from the interface between the barrier layer 108 and the doped gate layer 302 to distal from the barrier layer 108.

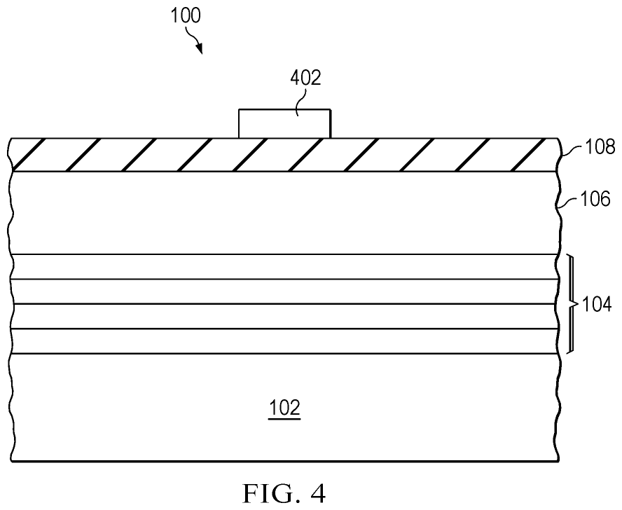

Referring to FIG. 4, the doped gate layer 302 is patterned into a patterned doped gate layer 402. The doped gate layer 302 may be patterned using appropriate photolithography and etch processes.

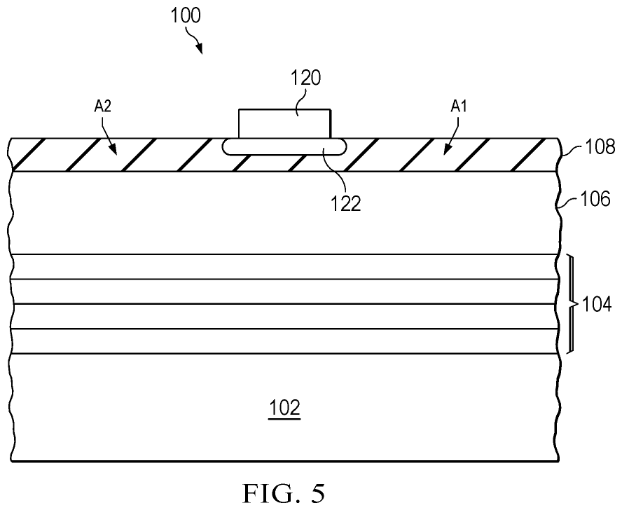

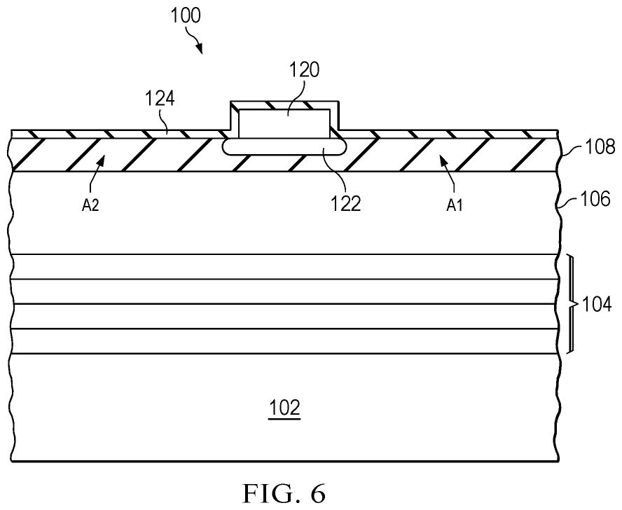

Referring to FIG. 5, a thermal process is performed to drive a dopant in the patterned doped gate layer 402 to diffuse into the barrier layer 108 to form the doped region 122. The thermal process may be an anneal step or any process step that may etch, deposit, etc. another material. The thermal process may be performed on the structure as illustrated in FIG. 5 and/or on a structure with additional layers and/or features, such as described below with respect to FIG. 6. In some examples, the thermal process includes using a process temperature of at least 800° C., such as in a range from 800° C. to 1,000° C. The thermal process causes diffusion of the dopant with which the patterned doped gate layer 402 was doped. Diffusion may cause a concentration of the dopant to become more uniform (e.g., having a lower gradient concentration) throughout the gate layer 120 as a result of the thermal process. The diffusion further causes the dopant to out-diffuse from the patterned doped gate layer 402 into the barrier layer 108 to thereby form the doped region 122. The patterning of the patterned doped gate layer 402 results in the diffusion of the dopant to be proximate to the patterned doped gate layer 402 (and thereby, the gate layer 120). This results in the concentration of the dopant in the doped region 122 to be greater than a concentration of the dopant in the first access region A1 and/or the second access region A2 in the barrier layer 108. Although some diffusion or implantation of the dopant into the first access region A1 and/or the second access region A2 in the barrier layer 108 may introduce the dopant into the first and/or second access regions A1, A2 prior to the thermal process, the diffusion of the dopant resulting from the thermal process causes the concentration of the dopant in the doped region 122 to be greater than a concentration of the dopant in the first access region A1 and/or the second access region A2 in the barrier layer 108. The concentrations of the dopant in the gate layer 120, doped region 122, the first access region A1, and the second access region A2 may be as described previously.

Referring to FIG. 6, a passivation layer 124 is formed over and on the gate layer 120 and barrier layer 108. The passivation layer 124 may be conformally deposited over and on the barrier layer 108 and along sidewall surfaces and over and on a top surface of the gate layer 120. The passivation layer 124 may be formed using any appropriate deposition process, such as LPCVD, atomic layer deposition (ALD), or the like. The deposition of the passivation layer 124, in some examples, may be the thermal process of FIG. 5, which drives dopants to diffuse into the barrier layer 108. More specifically, in examples in which LPCVD is used to form the passivation layer 124, the LPCVD process may include an annealing step, which may be the thermal process of FIG. 5 that drives dopants from the patterned doped gate layer 402 into the barrier layer 108. Example materials of the passivation layer 124 may be as described previously.

Referring to FIG. 1, the gate contact 126 is formed. An opening through the passivation layer 124 is formed to expose the gate layer 120 using appropriate photolithography and etching processes. A metal layer of the gate contact 126 is deposited on the passivation layer 124 and in the opening to contact the gate layer 120 using an appropriate deposition process, such as chemical vapor deposition (CVD), physical vapor deposition (PVD), or the like. The metal layer is patterned into the gate contact 126 using appropriate photolithography and etching processes.

The first dielectric layer 130 is formed over and on the passivation layer 124 and the gate contact 126. The first dielectric layer 130 may be deposited using any appropriate deposition process, such as plasma enhance CVD (PECVD) or the like. The first dielectric layer 130 may be planarized, such as by a chemical mechanical polish (CMP).

The metal via 132 is formed through the first dielectric layer 130 to the gate contact 126, and the metal line 136 is formed over and on the first dielectric layer 130. An opening may be formed through the first dielectric layer 130 to the gate contact 126 using appropriate photolithography and etching processes. A metal(s) of the metal via 132 and metal line 136 are deposited over the first dielectric layer 130 and in the opening through the first dielectric layer 130. The metal(s) may be deposited using an appropriate deposition process(es), such as CVD, PVD, or the like. The metal(s) may be patterned into the metal line 136 using appropriate photolithography and etching processes. The metal(s) underlying the metal line 136 and in the opening through the first dielectric layer 130 forms the metal via 132.

The second dielectric layer 140 is formed over and on the first dielectric layer 130 and the metal line 136. The second dielectric layer 140 may be deposited using any appropriate deposition process, such as PECVD or the like. The second dielectric layer 140 may be planarized, such as by a CMP.

The drain contact 142 and source contact 144 are formed through the second dielectric layer 140, first dielectric layer 130, and passivation layer 124 to the barrier layer 108 at the drain region D and source region S, respectively. The metal lines 152, 154 are formed over and on the second dielectric layer 140. Openings may be formed through the second dielectric layer 140, first dielectric layer 130, and passivation layer 124 to the barrier layer 108 at the drain region D and source region S using appropriate photolithography and etching processes. A metal(s) of the drain contact 142, source contact 144, and metal lines 152, 154 are deposited over the second dielectric layer 140 and in the openings through the second dielectric layer 140, first dielectric layer 130, and passivation layer 124. The metal(s) may be deposited using an appropriate deposition process(es), such as CVD, PVD, or the like. The metal(s) may be patterned into the metal lines 152, 154 using appropriate photolithography and etching processes. The metal(s) underlying the metal lines 152, 154 and in the respective openings through the second dielectric layer 140, first dielectric layer 130, and passivation layer 124 form the drain contact 142 and source contact 144.

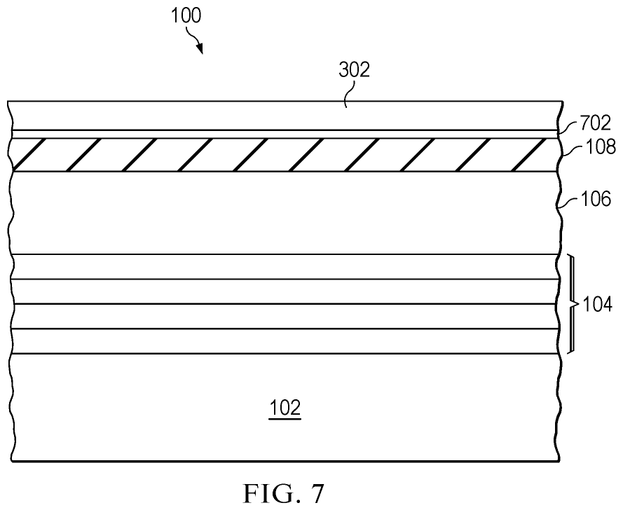

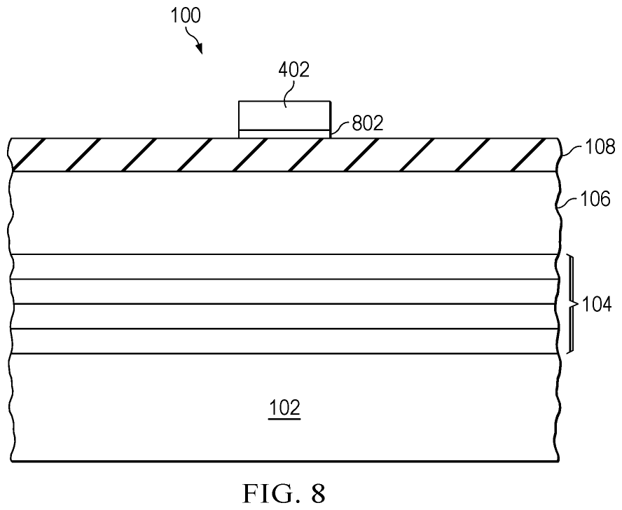

FIGS. 7 and 8 illustrate cross-sectional views of the semiconductor device 100 of FIG. 1 at various stages of a second method of manufacturing according to some examples. Processing proceeds as described above with respect to FIG. 2.

Referring to FIG. 7, an undoped gate layer 702 is formed over and on the barrier layer 108, and a doped gate layer 302 is formed over and on the undoped gate layer 702. In some examples, the undoped gate layer 702 and the doped gate layer 302 may be epitaxially grown, such as by MOCVD, MBE, LPCVD, PECVD, atomic layer epitaxy or another epitaxy process. A thickness of the undoped gate layer 702 may be less than 20 nm in some examples, such as greater than 0 nm and less than 20 nm. The undoped gate layer 702 may be an intrinsic semiconductor material (e.g., without a p-type or an n-type dopant). The doped gate layer 302 may be doped in situ during deposition or by implantation subsequent to deposition. In some examples, the undoped gate layer 702 may be or include the intrinsic semiconductor material of the doped gate layer 302. In some examples, the undoped gate layer 702 is or includes gallium nitride (GaN), or more generally, indium aluminum gallium nitride (InₓAl_{y}Ga_{1-x-y}N). In some examples, the undoped gate layer 702 is or includes a gallium nitride (GaN) layer, and the doped gate layer 302 is p-doped gallium nitride (pGaN). The doped gate layer 302 and/or dopant may be as described previously.

Referring to FIG. 8, the undoped gate layer 702 and the doped gate layer 302 are patterned into a patterned undoped gate layer 802 and a patterned doped gate layer 402, respectively. The undoped gate layer 702 and the doped gate layer 302 may be patterned using appropriate photolithography and etch processes.

Processing then proceeds as described with respect to FIGS. 5, 6, and 1. The thermal process of FIG. 5 (or as described herein with reference to FIG. 6) diffuses dopants into and through the patterned undoped gate layer 802, and further into the barrier layer 108 to form the doped region 122. The thermal process may result in a more uniform concentration (e.g., having a lower gradient concentration) of the dopant across the patterned undoped gate layer 802 and patterned doped gate layer 402 subsequent to the thermal process, which forms the gate layer 120. The undoped gate layer 702 (and subsequently, the patterned undoped gate layer 802) may form a buffer layer between the barrier layer 108 and the doped gate layer 302 (and subsequently, the patterned doped gate layer 402) prior to the thermal process by which dopants are driven from the patterned doped gate layer 402 into the barrier layer 108. The undoped gate layer 702 (and subsequently, the patterned undoped gate layer 802), as a buffer layer, may prevent some diffusion of the dopants during processing prior to the thermal process such that less dopants diffuse into, e.g., the first access region A1 and the second access region A2.

Although various examples have been described in detail, it should be understood that various changes, substitutions, and alterations can be made therein without departing from the scope defined by the appended claims.

What is claimed is:

1. A semiconductor device, comprising:
a channel layer over a semiconductor substrate;
a barrier layer over the channel layer; and
a gate layer over the barrier layer, the gate layer being doped with a dopant, wherein:
a first region in the barrier layer overlies a channel region in the channel layer and underlies the gate layer, the first region having a first concentration of the dopant; and
a second region in the barrier layer laterally disposed from the first region, the second region having a second concentration of the dopant that is less than the first concentration.

2. The semiconductor device of claim 1, wherein the first concentration is an order of magnitude or more greater than the second concentration.

3. The semiconductor device of claim 1, wherein the dopant is a p-type dopant.

4. The semiconductor device of claim 1, wherein the dopant includes magnesium, carbon, or a combination thereof.

5. The semiconductor device of claim 1, wherein the first concentration is 1×10¹⁶ cm⁻³ or greater.

6. The semiconductor device of claim 1, wherein the second concentration is 1×10¹⁹ cm⁻³ or less.

7. The semiconductor device of claim 1, wherein:
the channel layer includes gallium nitride (GaN);
the barrier layer includes aluminum gallium nitride (AlGaN); and
the gate layer includes magnesium doped gallium nitride (GaN: Mg).

8. The semiconductor device of claim 1, further comprising:
a passivation layer over the gate layer and the barrier layer; and
a gate contact over and contacting the gate layer and through the passivation layer.

9. A method, comprising:
forming a doped gate layer over a barrier layer, the doped gate layer being doped with a dopant while forming the doped gate layer, wherein:
the barrier layer is over a channel layer; and
the channel layer is over a semiconductor substrate;
patterning the doped gate layer; and
after patterning the doped gate layer, performing a thermal process on the doped gate layer and the barrier layer, wherein the thermal process causes the dopant to diffuse from the doped gate layer into the barrier layer.

10. The method of claim 9, further comprising:
forming an undoped gate layer over the barrier layer, wherein the doped gate layer is formed over the undoped gate layer.

11. The method of claim 9, wherein forming the doped gate layer includes epitaxially growing the doped gate layer including:
growing the doped gate layer at a processing temperature in a range from 800° C. to 1,050° C.;
growing the doped gate layer at a processing pressure in a range from 100 millibar (mbar) to 500 mbar; and
flowing a dopant-source gas at a flow rate in a range up to 1,000 standard cubic centimeter per minute (sccm), the dopant-source gas being a source of the dopant.

12. The method of claim 11, wherein epitaxially growing the doped gate layer includes increasing the flow rate of the dopant-source gas while epitaxially growing the doped gate layer, the dopant-source gas being a source of the dopant.

13. The method of claim 9, wherein the thermal process includes a processing temperature of at least 800° C.

14. The method of claim 9, wherein after performing the thermal process:
a first region in the barrier layer overlies a channel region in the channel layer and underlies the doped gate layer;
the first region has a first concentration of the dopant;
a second region in the barrier layer laterally disposed from the first region; and
the second region has a second concentration of the dopant that is less than the first concentration.

15. The method of claim 14, wherein the first concentration is an order of magnitude or more greater than the second concentration.

16. The method of claim 9, wherein the dopant includes magnesium, carbon, or a combination thereof.

17. The method of claim 9, further comprising:
forming a passivation layer over the doped gate layer and the barrier layer;
forming an opening through the passivation layer to the doped gate layer;
forming a metal in the opening and contacting the doped gate layer; and
patterning the metal to form a gate contact over and contacting the doped gate layer.

18. A semiconductor device, comprising:
a GaN channel layer over a semiconductor substrate;
an AlGaN barrier layer over the GaN channel layer;
a doped GaN gate layer on the AlGaN barrier layer;
a drain contact contacting the AlGaN barrier layer, wherein:
the doped GaN gate layer includes a p-type dopant;
a first portion of the AlGaN barrier layer under the doped GaN gate layer includes a first concentration of the p-type dopant; and
a second portion of the AlGaN barrier layer between the doped GaN gate layer and the drain contact includes a second concentration of the p-type dopant less than the first concentration.

19. The semiconductor device of claim 18, wherein the first concentration is greater than the second concentration by an order of magnitude or more.

20. The semiconductor device of claim 18, wherein:
the first portion of the AlGaN barrier layer overlies a channel region in the GaN channel layer; and
the second portion of the AlGaN barrier layer includes an access region in the AlGaN barrier layer.

21. The semiconductor device of claim 18, wherein the p-type dopant in the first portion of the AlGaN barrier layer extends from an interface between the doped GaN gate layer and the AlGaN barrier layer toward the GaN channel layer.

22. The semiconductor device of claim 18, further comprising:
a passivation layer over the doped GaN gate layer and the AlGaN barrier layer; and
a gate contact over and contacting the doped GaN gate layer and through the passivation layer.
